(19) United States
(12) Patent Application Publication
(10) Pub. No.: US 2011/0005797 A1
(43) Pub. Date: Jan. 13, 2011

(54) DEVICE HOUSING AND METHOD FOR MAKING DEVICE HOUSING

(75) Inventors: BEN-DING TSAO, Shindian (TW); JIAN-MING LIU, Shenzhen City (CN); XUE-YUN ZU, Shenzhen City (CN); ZHEN-QIU ZHOU, Shenzhen City (CN); BIN ZHANG, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/749,638

(22) Filed: Mar. 30, 2010

(30) Foreign Application Priority Data
Jul. 10, 2009 (CN) 200910304237.8

(51) Int. Cl. H05K 5/00; B32B 37/00; C09J 163/00; C09J 175/04; B32B 37/12

(52) U.S. Cl. 174/50; 156/60; 156/330; 156/331.7; 156/326

(57) ABSTRACT

A method for making a device housing comprises: providing a metal substrate; providing a transparent or translucent film, the film being formed with a pattern coating on one surface thereof; forming a bonding coating on the metal substrate; and heat pressing the film and the metal substrate into a whole with the pattern coating bonding with the bonding coating. A device housing manufactured by the method is also described there.

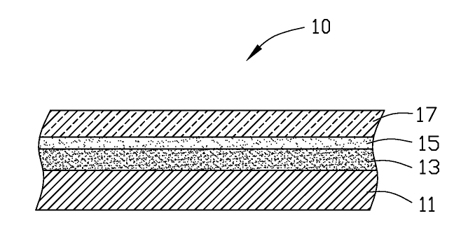

### BACKGROUND

1. Technical Field

The present disclosure relates to device housings, especially to a device housing having high strength and an attractive appearance, and a method for making the device housing.

2. Description of Related Art

In Molding Label (IML) process is a frequently used method for producing housings of portable electronic devices. The process is carried out by molding a plastic substrate in a mold in combination with a plastic film. Before the substrate is molded, a pattern may be printed on the film, and the molded substrate is bonded with the patterned film, such that, the pattern is protected from damage by being positioned between the film and the substrate. However, the housing may have a low strength. To enhance the strength, a metal substrate may be used. However, metal commonly has a melting temperature so high that the patterned film may be damaged during the molding process.

Therefore, there is room for improvement within the art.

### BRIEF DESCRIPTION OF THE FIGURE

Many aspects of the device housing can be better understood with reference to the following figure. The components in the figures are not necessarily drawn to scale, the emphasis instead being placed upon clearly illustrating the principles of the device housing.

The figure is a cross-sectional view of an exemplary embodiment of a device housing.

### DETAILED DESCRIPTION

A method for manufacturing a device housing, in this exemplary embodiment, includes: providing a metal substrate; providing a transparent or translucent film, the film being formed with a pattern coating on one surface thereof; forming a bonding coating on the metal substrate; and heat pressing the film and the metal substrate into a whole with the pattern coating bonding with the bonding coating.

Referring to the figure, a metal substrate 11 is provided. The metal substrate 11 may have the shape of a device housing. The metal substrate 11 includes an outer surface and an inner surface. The metal substrate 11 may be made of magnesium alloy, aluminum alloy or iron.

A film 17 is provided. The film 17 may be a transparent or translucent plastic coating having a thickness of about 0.1-0.6 mm. The plastic may be selected from a group consisting of polypropylene (PP), polyamide (PA), polycarbonate (PC), polyethylene terephthalate (PET), and polymethyl methacrylate (PMMA).

A pattern coating 15 is printed on one surface of the film 17. The pattern coating 15 may be a colored transparent or translucent ink coating.

The film 17 formed with the pattern coating 15 is then heat pressed to the shape of a device housing, and the surface of the film 17 having the pattern coating 15 forms an inner surface during the heat pressing process.

A bonding coating 13 is sprayed on the outer surface of the metal substrate 11 and then dried. The bonding coating 13 may be polyurethane adhesive, epoxy resin adhesive, or acrylic acid adhesive. The bonding coating 13 may be transparent and has a thickness of about 0.03-0.1 mm.

The film 17 and the metal substrate 11 are laminated together with the pattern coating 15 contacting the bonding coating 13 and then heat pressed into an integrated whole to obtain a device housing 10.

Referring to the figure, in an exemplary embodiment, the device housing 10 formed by the method includes a metal substrate 11, a bonding coating 13 formed on the metal substrate 11, a pattern coating 15 bonded with the bonding coating 13, and a film 17 bonded with the pattern coating 15. The film 17 may be a transparent or translucent plastic coating. The pattern coating 15 may be a colored transparent or translucent ink coating. The pattern coating 15 can be protected from abrasion by being positioned under the film 17. The metal substrate 11 gives the device housing 10 a metallic appearance and greater strength. The pattern coating 15 is observable and aesthetic.

The device housing 10 may be, for example, a housing of a mobile phone, a note-book computer, or a digital camera.

It should be understood, however, that even though numerous characteristics and advantages of the present embodiments have been set forth in the foregoing description, together with details of functions of the embodiments, the disclosure is illustrative only, and changes may be made in detail within the principles of the disclosure to the full extent indicated by the broad general meaning of the terms in which the appended claims are expressed.

What is claimed is:

1. A method for making device housing, comprising:
providing a metal substrate;
providing a transparent or translucent film, the film being formed with a pattern coating on one surface thereof;
forming a bonding coating on the metal substrate; and
heat pressing the film and the metal substrate into a whole such that the pattern coating on the film bonds with the bonding coating on the metal substrate.

2. The method as claimed in claim 1, wherein the metal substrate is made of magnesium alloy, aluminum alloy, or iron.

3. The method as claimed in claim 1, wherein the film is a plastic coating having a thickness of about 0.1-0.6 mm.

4. The method as claimed in claim 3, wherein the plastic is selected from a group consisting of polypropylene, polyamide, polycarbonate, polyethylene terephthalate, and polymethyl methacrylate.

5. The method as claimed in claim 1, wherein the bonding coating is formed on one of the surface of the metal substrate by spraying.

6. The method as claimed in claim 1, wherein the bonding coating has a thickness of about 0.03-0.1 mm.

7. The method as claimed in claim 1, wherein the bonding coating is polyurethane adhesive, epoxy adhesive, or acrylic acid adhesive.

8. The method as claimed in claim 1, wherein the pattern coating is a colored transparent or translucent ink coating.

9. A device housing, comprising:
a metal substrate;
a bonding coating formed on one surface of the metal substrate;
a pattern coating formed on the bonding coating; and
a transparent or translucent film formed on the pattern coating;
wherein the device housing is obtained by heat pressing the film and the metal substrate into a whole with the pattern coating bonding with the bonding coating.

10. The device housing as claimed in claim 9, wherein the metal substrate is made of magnesium alloy, aluminum alloy, or iron.

11. The device housing as claimed in claim 9, wherein the film is a plastic coating having a thickness of about 0.1-0.6 mm.

12. The device housing as claimed in claim 11, wherein the plastic is selected from a group consisting of polypropylene, polyamide, polycarbonate, polyethylene terephthalate, and polymethyl methacrylate.

13. The device housing as claimed in claim 9, wherein the bonding coating is formed on one of the surface of the metal substrate by spraying.

14. The device housing as claimed in claim 9, wherein the bonding coating has a thickness of about 0.03-0.1 mm.

15. The device housing as claimed in claim 9, wherein the bonding coating is polyurethane adhesive, epoxy adhesive, or acrylic acid adhesive.

16. The device housing as claimed in claim 9, wherein the pattern coating is a colored transparent or translucent ink coating.
